(19) United States
(12) Patent Application Publication
(10) Pub. No.: US 2011/0088762 A1
(43) Pub. Date: Apr. 21, 2011

(54) BARRIER LAYER DISPOSED BETWEEN A SUBSTRATE AND A TRANSPARENT CONDUCTIVE OXIDE LAYER FOR THIN FILM SILICON SOLAR CELLS

(75) Inventors: Kaushal K. Singh, Santa Clara, CA (US); Deepak Pingalay, Campbell, CA (US); Suresh Shrauti, Dallas, TX (US)

(73) Assignee: APPLIED MATERIALS, INC., Santa Clara, CA (US)

(21) Appl. No.: 12/879,627

(22) Filed: Sep. 10, 2010

Related U.S. Application Data
(60) Provisional application No. 61/251,995, filed on Oct. 15, 2009.

(51) Int. Cl. H01L 31/0248; H01L 31/0224

(52) U.S. Cl. 136/255; 438/98; 257/E31.126

(57) ABSTRACT

A method and apparatus for forming solar cells is provided. In one embodiment, a photovoltaic device includes a barrier layer disposed on a substrate, a TCO layer disposed on the barrier layer, and a p-i-n junction cell formed on the TCO layer. In another embodiment, a method for forming a photovoltaic device includes providing a substrate having a surface, forming a barrier layer on the surface of the substrate, forming a TCO layer on a top surface of the barrier layer, and forming a p-i-n junction cell on the TCO layer.

### CROSS-REFERENCE TO RELATED APPLICATIONS

This application claims benefit of U.S. Provisional Application Ser. No. 61/251,995 filed Oct. 15, 2009 (Attorney Docket No. APPM/14449L), which is incorporated by reference in their entirety.

### BACKGROUND OF THE INVENTION

1. Field of the Invention

Embodiments of the present invention generally relate to solar cells and methods for forming the same. More particularly, embodiments of the present invention relate to a barrier layer disposed between a substrate and a transparent conductive oxide (TCO) film layer in thin film solar cell applications.

2. Description of the Related Art

Solar cells convert solar radiation and other light into usable electrical energy. The energy conversion occurs as the result of the photovoltaic effect. Solar cells may be formed from crystalline material or from amorphous or micro-crystalline materials. Generally, there are two major types of solar cells that are produced in large quantities today, which are crystalline silicon solar cells and thin film solar cells. Crystalline silicon solar cells typically use either mono-crystalline substrates (i.e., single-crystal substrates of pure silicon) or a multi-crystalline silicon substrates (i.e., poly-crystalline or polysilicon). Additional film layers are deposited onto the silicon substrates to improve light capture, form the electrical circuits, and protect the devices. Thin film solar cells use thin layers of materials deposited on suitable substrates to form one or more p-n junctions. Suitable substrates include glass, metal, and polymer substrates. It has been found that the properties of thin film solar cells degrade over time upon exposure to light, which can cause the device stability to be less than desired. Typical solar cell properties that may degrade are the fill factor (FF), short circuit current, and open circuit voltage (Voc).

Several types of thin film solar cells including microcrystalline silicon film (μc-Si), amorphous silicon film (a-Si), polycrystalline silicon film (poly-Si) and the like are being utilized to form thin film solar cells. A transparent conductive film or a transparent conductive oxide (TCO) film is often used as a surface electrode, often referred as a reflector, disposed on the top or the bottom of the thin film solar cells. The transparent conductive oxide (TCO) film must have high optical transmittance in the visible or higher wavelength region to facilitate transmitting sunlight into the solar cells without adversely absorbing or reflecting light energy. Also, low contact resistance and high electrical conductivity of the transparent conductive oxide (TCO) film are desired to provide high photoelectric conversion efficiency and electricity collection.

It is observed that growth and film morphology of the TCO film is very sensitive to nature of the substrate. Different substrate materials may significantly influence the nucleation capability and grain growth of the TCO film formed thereon. Poor nucleation or adhesion of the TCO film formed on the substrate may result in film peeling or cracking at the interface, high contact resistance, and poor optical and electrical film properties. High contact resistance at the interface of the TCO film and adjacent films may reduce carrier mobility within the thin film solar cells. Furthermore, non-uniform grain growth may result in small random grains formed in the initial stage of the TCO film deposition process, thereby increasing the likelihood of forming defects and pinholes at the interface between the TCO film layer and the substrate, which may adversely affect the optical and electrical properties of the formed TCO film layer.

Therefore, there is a need for an improved method for forming a transparent conductive film with high interface qualities on a substrate surface for thin film solar cells.

### SUMMARY OF THE INVENTION

Embodiments of the invention provide methods of forming a barrier layer between a TCO layer and a substrate to improve interface properties. In one embodiment, a photovoltaic device includes a barrier layer disposed on a substrate, a TCO layer disposed on the barrier layer, and a p-i-n junction cell formed on the TCO layer.

In another embodiment, a method for forming a photovoltaic device includes providing a substrate having a surface, forming a barrier layer on the surface of the substrate, forming a TCO layer on a top surface of the barrier layer, and forming a p-i-n junction cell on the TCO layer.

In yet another embodiment, a photovoltaic device includes a first dielectric layer disposed on a substrate, a second dielectric layer disposed on the first dielectric layer on the substrate, wherein the second dielectric layer has a top surface having a nitrogen concentration less than 40 weight percent, a TCO layer disposed on the second dielectric layer, and a p-i-n junction cell formed on the TCO layer.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a conventional schematic side-view of a single junction thin-film solar cell;

FIG. 2A depicts a schematic side-view of a single junction thin-film solar cell having a barrier layer disposed between a substrate and a TCO layer according to one embodiment of the invention;

FIG. 2B depicts an enlarged view of barrier layer disposed between the substrate and the TCO layer of FIG. 2A;

FIG. 3 depicts a flow diagram of a process sequence for fabricating a barrier layer disposed between a substrate and a TCO layer with one embodiment of the present invention;

FIG. 4 depicts a schematic side-view of a tandem junction thin-film solar cell having a barrier layer disposed between a substrate and a TCO layer according to one embodiment of the invention; and

FIG. 5 depicts a cross-sectional view of an apparatus that may be utilized to form a barrier layer and a TCO layer according to one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments

### DETAILED DESCRIPTION

Thin-film solar cells are generally formed from numerous types of films, or layers, put together in many different ways. Most films used in such devices incorporate a semiconductor element that may comprise silicon, germanium, carbon, boron, phosphorous, nitrogen, oxygen, hydrogen and the like. Characteristics of the different films include degrees of crystallinity, dopant type, dopant concentration, film refractive index, film extinction coefficient, film transparency, film absorption, conductivity, thickness and roughness. Most of these films can be formed by use of a chemical vapor deposition process, which may include some degree of ionization or plasma formation.

Charge generation during a photovoltaic process is generally provided by a bulk semiconductor layer, such as a silicon containing layer. The bulk layer is also sometimes called an intrinsic layer to distinguish it from the various doped layers present in the solar cell. The intrinsic layer may have any desired degree of crystallinity, which will influence its light-absorbing characteristics. For example, an amorphous intrinsic layer, such as amorphous silicon, will generally absorb light at different wavelengths compared to intrinsic layers having different degrees of crystallinity, such as microcrystalline or nanocrystalline silicon. For this reason, it is advantageous to use both types of layers to yield the broadest possible absorption characteristics.

Silicon and other semiconductors can be formed into solids having varying degrees of crystallinity. Solids having essentially no crystallinity are amorphous, and silicon with negligible crystallinity is referred to as amorphous silicon. Completely crystalline silicon is referred to as crystalline, polycrystalline, or monocrystalline silicon. Polycrystalline silicon is crystalline silicon including numerous crystal grains separated by grain boundaries. Monocrystalline silicon is a single crystal of silicon. Solids having partial crystallinity, that is a crystal fraction between about 5% and about 95%, are referred to as nanocrystalline or microcrystalline, generally referring to the size of crystal grains suspended in an amorphous phase. Solids having larger crystal grains are referred to as microcrystalline, whereas those with smaller crystal grains are nanocrystalline. It should be noted that the term “crystalline silicon” may refer to any form of silicon having a crystal phase, including microcrystalline, nanocrystalline, monocrystalline and polycrystalline silicon.

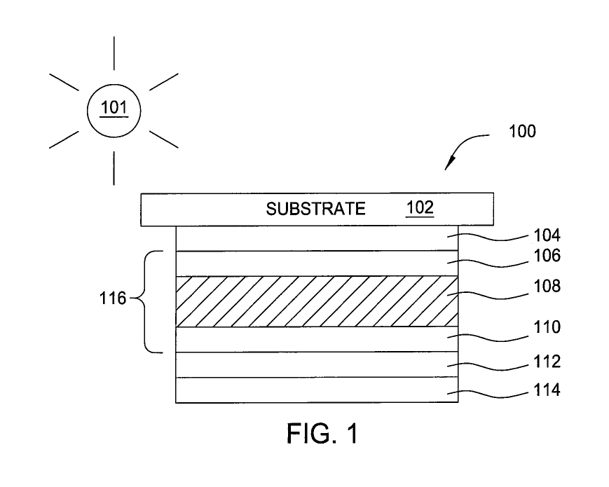

FIG. 1 is a conventional schematic diagram of an embodiment of a single junction solar cell 100 oriented toward a light or solar radiation 101. The solar cell 100 includes a substrate 102. A first transparent conductive oxide (TCO) layer 104 formed over the substrate 102, a first p-i-n junction 116 formed over the first TCO layer 104. A second TCO layer 112 is formed over the first p-i-n junction 116, and a metal back layer 114 is formed over the second TCO layer 112. The substrate 102 may be a glass substrate, polymer substrate, or other suitable substrate, with thin films formed thereover.

The first TCO layer 104 and the second TCO layer 112 may each comprise tin oxide, zinc oxide, indium tin oxide, cadmium stannate, combinations thereof, or other suitable materials. It is understood that the TCO materials may also additionally include dopants and other components. For example, zinc oxide may further include dopants, such as tin, aluminum, gallium, boron, and other suitable dopants. In certain instances, the substrate 102 may be provided by the glass manufacturers with the first TCO layer 104 already deposited thereon.

To improve light absorption by enhancing light trapping, the substrate 102 and/or one or more of thin films formed may be optionally textured by wet, plasma, ion, and/or mechanical texturing process. For example, in the embodiment shown in FIG. 1, the first TCO layer 104 may be textured (not shown) so that the topography of the surface is substantially transferred to the subsequent thin films deposited thereafter.

The first p-i-n junction 116 may comprise a p-type silicon containing layer 106, an intrinsic type silicon containing layer 108 formed over the p-type silicon containing layer 106, and an n-type silicon containing layer 110 formed over the intrinsic type silicon containing layer 108. In certain embodiments, the p-type silicon containing layer 106 is a p-type amorphous or microcrystalline silicon layer having a thickness between about 60 Å and about 300 Å. In certain embodiments, the intrinsic type silicon containing layer 108 is an intrinsic type amorphous and microcrystalline mixed silicon layer having a thickness between about 500 Åand about 2 μm. In certain embodiments, the n-type silicon containing layer 110 is a n-type microcrystalline silicon layer may be formed to a thickness between about 100 Åand about 400 Å.

The metal back layer 114 may include, but not limited to a material selected from the group consisting of Al, Ag, Ti, Cr, Au, Cu, Pt, alloys thereof, and combinations thereof. Other processes may be performed to form the solar cell 100, such as a laser scribing processes. Other films, materials, substrates, and/or packaging may be provided over metal back layer 114 to complete the solar cell device. The formed solar cells may be interconnected to form modules, which in turn can be connected to form arrays.

Solar radiation 101 is primarily absorbed by the intrinsic layers 108 of the p-i-n junction 116 and is converted to electron-holes pairs. The electric field created between the p-type layer 106 and the n-type layer 110 that extends across the intrinsic layer 108 causes electrons to flow toward the n-type layers 110 and holes to flow toward the p-type layers 106 creating a current. The p-i-n junction 116 comprises the intrinsic layer 108 to capture a large portion of the solar radiation spectrum.

Charge collection is generally provided by doped semiconductor layers, such as silicon layers doped with p-type or n-type dopants. In silicon based layers, p-type dopants are generally Group III elements, such as boron or aluminum while n-type dopants are generally Group V elements, such as phosphorus, arsenic, or antimony. In most embodiments, boron is used as the p-type dopant and phosphorus as the n-type dopant. These dopants may be added to the p-type and n-type layers 106, 110 respectively described above by including boron-containing or phosphorus-containing compounds in the reaction mixture. Suitable boron and phosphorus compounds generally comprise substituted and unsubstituted lower borane and phosphine oligomers. Some suitable boron containing dopant compounds include trimethylboron (B(CH₃)₃ or TMB), diborane (B₂H₆), boron trifluoride (BF₃), and triethylboron (B(C₂H₅)₃ or TEB). Phosphine (PH₃) is the most common phosphorus containing dopant compound. The dopants are generally provided with a carrier gas, such as hydrogen, helium, argon, or other suitable gas. If hydrogen is used as the carrier gas, the total hydrogen in the reaction mixture is increased. Thus, the hydrogen ratios discussed below will include the portion of hydrogen contributed carrier gas used to deliver the dopants.

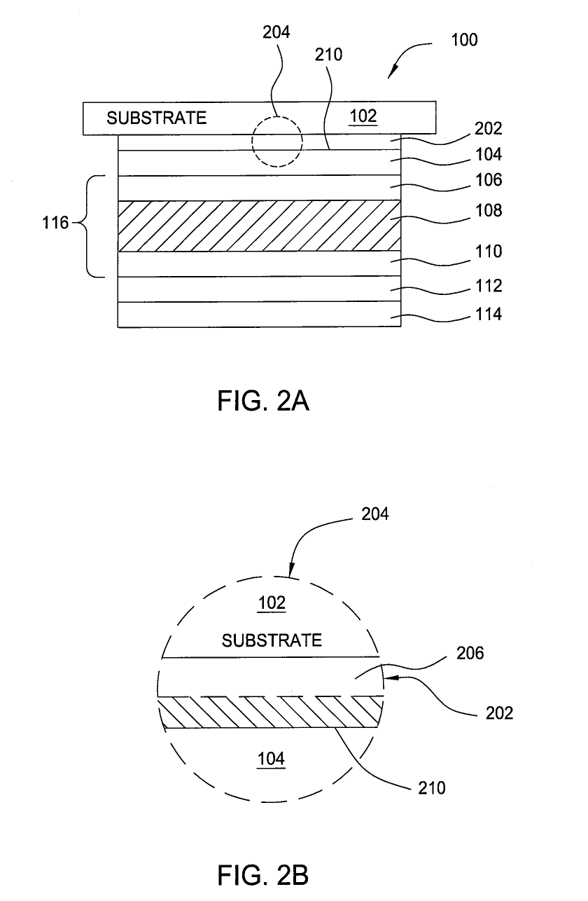

As discussed above, formation of the TCO layer 104 on the substrate 102 may be highly influenced by nature of the surface where the TCO layer 104 is formed thereon. The substrate surface often has contaminants, impurities, or surface adhesives that may impact on the nucleation of the grains when forming the TCO layer 104 thereon. Furthermore, these contaminants may also influence on the grain growth and lattice growth orientation of the TCO layer 104, thereby resulting in poor crystalline structure formed in the TCO layer 104 and further reducing electrical and optical properties of the TCO layer 104. Accordingly, a barrier layer 202, as depicted in FIG. 2A, is formed on the surface of the substrate 102 prior to the deposition of the TCO layer 104 to maintain and provide a consistent contact surface for the TCO layer 104 to be formed thereon.

It is believed that a contact surface that contains high concentration of nitrogen atoms may adversely retard the nucleation process when forming the TCO layer 104 thereon. Accordingly, providing the barrier layer 202 having a contact surface 210 with low nitrogen concentration is believed to assist growth of grain and nucleation site of the TCO layer on the barrier layer 202. In one embodiment, the barrier layer 202 may be a dielectric layer having a low nitrogen concentration on the contact surface 210 of the barrier layer 202 that will be in contact with the TCO layer 104. In one embodiment, the barrier layer 202 may have a nitrogen concentration less than about 40 weight percent. In one embodiment, the barrier layer 202 may be a silicon oxynitride layer (SiON) having a nitrogen concentration about less than 40 weight percent and having an oxygen concentration about greater than 60 weight percent. It is also believed that high oxygen concentration and/or low nitrogen concentration of the barrier layer 202 assists nucleation site growth and grain growth of the TCO layer 104 on the barrier layer 202, thereby improving adhesion and film interface properties of the TCO layer 104. As such, by controlling film properties of the oxygen concentration of the barrier layer 202 above a certain degree, such as greater than 60 weight percent, and/or the nitrogen concentration lower than a certain degree, such as less than 40 weight percent, a smooth, columnar grain growth of the TCO layer 104 at the interface may be obtained, thereby providing the TCO layer 104 with desired electrical and optical properties.

In another embodiment, the barrier layer 202 may be fabricated by aluminum oxide (Al₂O₃), titanium oxide (TiO₂), silicon oxide (SiO₂), zirconium oxide (ZrO₂), hydrogenated silicon nitride (SiNₓH_{y}), carbon doped silicon oxide (SiOC), the combination of silicon oxide (SiO₂) and titanium oxide (TiO₂), the combination of silicon oxide (SiO₂) and zirconium oxide (ZrO₂), or any combinations thereof. The barrier layer 202 may be deposited by any suitable deposition techniques, such as CVD, PVD, plating, epi, spaying coating or the like. It is believed that barrier layer 202 as formed between the substrate 102 and the TCO layer 104 may assist preventing impurities from the substrate 102 from diffusing into the TCO layer 104 or other adjacent layers used for forming the junction cells. In one embodiment, the barrier layer 102 as formed may efficiently prevent the sodium (Na) element from the substrate 102, if any, forming diffusing into the TCO layer 104 so as to preserve a high film quality and purity of the TCO layer 104.

Furthermore, the barrier layer 202 as described in the present invention also serves as a matching layer that can bridge the refractive index difference and the thermal expansion difference between the substrate 102 and the TCO layer 104. As the refractive index of the substrate 102 is typically around 1.5 and the refractive index of the TCO layer 104 is typically around 1.8, the barrier layer 202 as formed here is adjusted to provide a film refractive index between about 1.5 and 1.8 to assist smoothly transmitting sunlight from the substrate 102 through the barrier layer 202 and the TCO layer 104 to the junction cells 116 without undesired absorption loss and unwanted light reflection. Furthermore, similarly, as each material may have different thermal expansion coefficient, the material selected to fabricate the barrier layer 202 is configured to have a thermal expansion coefficient between the thermal expansion coefficient of the substrate 102 and the TCO layer 104. In one embodiment, the thermal expansion coefficient of the barrier layer 202 is controlled at between about 0.1 E-7/degree Celsius and about 90 E-7/degree Celsius. Accordingly, the barrier layer 202 as described here can efficiently provide a material interface that can efficiently bridge the material property difference, including surface morphology, refractive index difference and thermal coefficient difference, between the substrate 102 and the TCO layer 104 so as to minimize light reflection and absorption loss caused by the difference of the material properties. Furthermore, as described above, the barrier layer 202 as formed may efficiently block the impurities from the substrate 102 so as to maintain the film layers formed for the junction cell 116 at a desired level of purity as needed.

In one embodiment, the barrier layer 202 may be controlled to have a film thickness between about 500 Åand about 8000 Å, such as between about 700 Åand about 7000 Å, for example between about 800 Åand about 1800 Å.

In another embodiment, the low nitrogen concentration and/or the high oxygen concentration on the contact surface 210 of the barrier layer 202 may be achieved by performing a surface treatment process to drive out excessive or unwanted nitrogen atoms that may be present on the surface 210 of the barrier layer 202. For example, an oxygen surface treatment process may be performed to treat the contact surface 210 of the barrier layer 202 with oxygen containing gas, thereby incorporating oxygen atoms into the barrier layer 202 and driving out or pushing the nitrogen atoms down and away from the surface 210. As such, an oxygen rich surface with low nitrogen concentration may be obtained to assist growth of the TCO layer 104 that will be formed on the barrier layer 202. The gas selected to treat the contact surface 210 may include oxygen containing gas, such as O₂, N₂O, NO₂, H₂O, or other suitable gases.

In another embodiment, an inert gas treatment process, or other types of gas treatment process may be performed to drive out or densify the contact surface 210 of the barrier layer 202 so as to reduce the nitrogen concentration on the contact surface 210 of the barrier layer 202. For example, argon, helium, hydrogen, or other suitable types of the gas treatment process may be performed to drive out impurities and unwanted nitrogen atoms away from the surface 210 of the barrier layer 202, so that the nitrogen induced surface deposition retardation may be efficiently eliminated.

In the exemplary embodiment depicted in FIG. 2B, as the surface treatment process performed on the contact surface 210 of the barrier layer 202, the barrier layer 202 may become a gradient layer having an upper layer 208 with relatively low nitrogen concentration and a lower layer 206 with relatively higher nitrogen concentration. Alternatively, the barrier layer 202 may be formed by a multiple step deposition process to form the barrier layer 202 as two separate layers 206, 208, each layer 206, 208 having different film properties as desired. For example, the barrier layer 202 may be formed with the upper layer 208 having an oxygen rich surface and low nitrogen concentration to be in contact with the TCO layer 104. Accordingly, the lower layer 206 may be any dielectric layer that may provide good adhesion to the upper layer 208 as well as a consistent contact interface to the upper layer 208. In yet another embodiment, the barrier layer 202 may be formed as multiple layers having different element/atom concentration profile in each layers, so that when different film requirements are needed to be in contact with the TCO layer 104, the film qualities of the surface 210 of the barrier layer 202 may be adjusted as needed.

In one embodiment, the lower layer 206 may have a thickness between about 600 Åand about 1200 Å, such as about 800 Åand the upper layer 208 may have a thickness between about 200 Åand about 600 Å, such as about 400 Å.

It is believed that the barrier layer 202 having a high intensity of crystal orientation plane (002) rather the crystal orientation plane (101) will assist the TCO layer 104 formed thereon with a desired grain structure, thereby providing a high quality film structure and high film transmittance of the TCO layer 104. It is believed that the crystal orientation plane (002) formed in the barrier layer 202 may assist forming the TCO layer 104 with higher amount of columnar structure and greater size of the grains, thereby serving as a good surface for TCO layer 104 to nucleate thereon. Accordingly, it is desired to grow the barrier layer 202 with crystal orientation plane (002) rather than crystal orientation plane (101) so as to provide a good interface to deposit the TCO layer 104 with high film transmittance and desired film qualities.

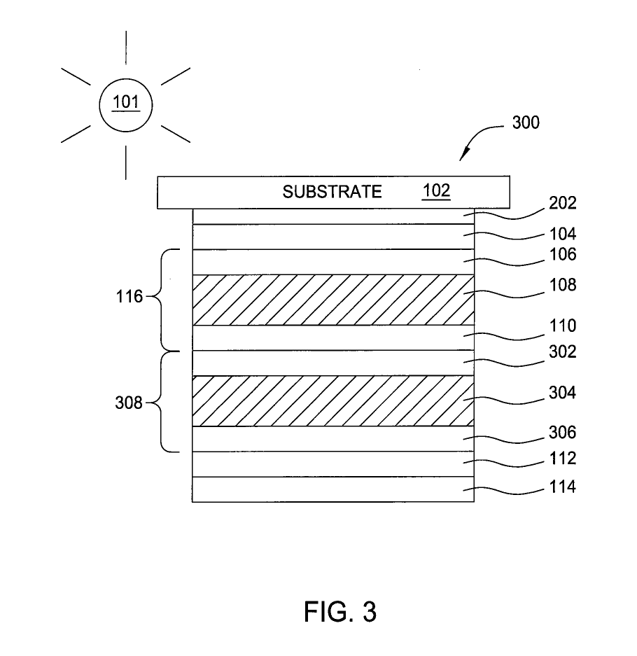

FIG. 3 depicts a schematic side-view of a tandem junction thin-film solar cell 300 having a barrier layer 202, such as the barrier layer 202 depicted in FIG. 1, according to one embodiment of the invention. In addition to the structure of the solar cell 100 depicted in FIG. 1, a second p-i-n junction 308 may be formed between the first p-i-n junction 116 and the second TCO layer 112. The second p-i-n junction 308 may have a p-type silicon containing layer 302, an intrinsic type silicon containing layer 304, and a n-type silicon containing layer 306. The p-type silicon containing layer 302, intrinsic type silicon containing layer 304 and the n-type silicon containing layer 306 formed in the second p-i-n junction 308 may be deposited in the same or similar manner as p-type silicon containing layer 106, intrinsic type silicon containing layer 108 and the n-type silicon containing layer 110 formed in the first p-i-n junction 116 described with reference to in FIG. 1. The barrier layer 202 formed between the substrate 102 and the TCO layer 104 may also be formed in the same or similar manner as the barrier layer 202 described with reference to in FIGS. 1 and 2A-2B.

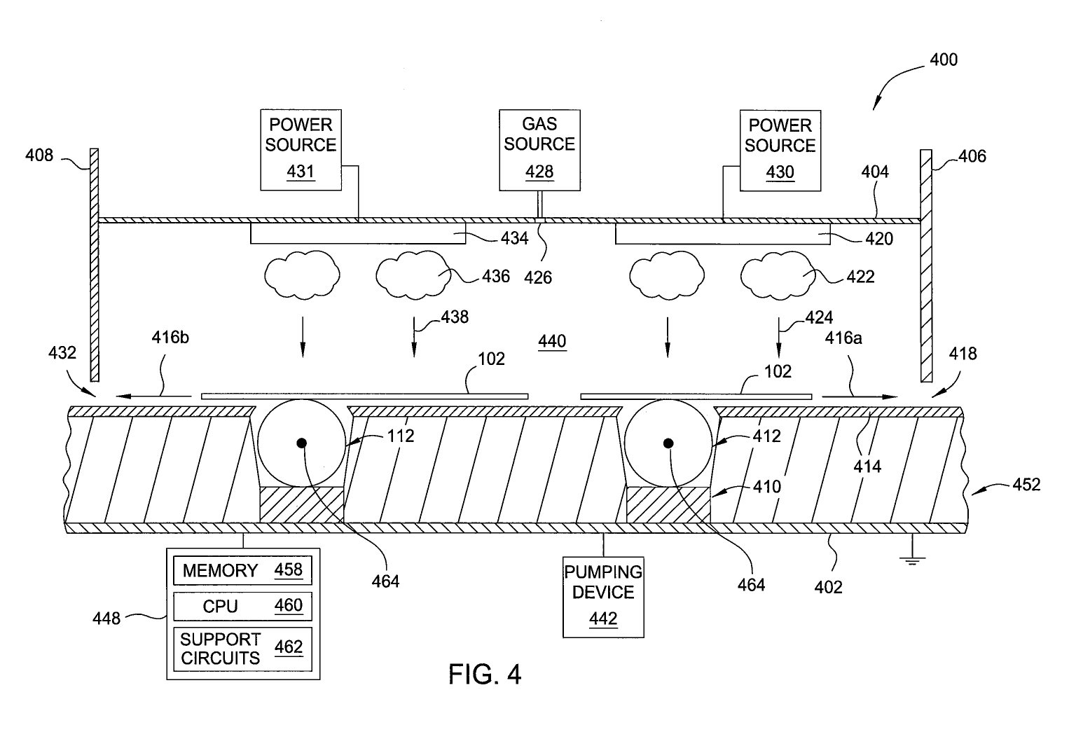

FIG. 4 illustrates an exemplary reactive sputter process chamber 400 suitable for sputter depositing materials to form the barrier layer 202 and the TCO layer 104 according to one embodiment of the invention. One example of the process chamber that may be adapted to benefit from the invention is a PVD process chamber, available from Applied Materials, Inc., located in Santa Clara, Calif. It is contemplated that other sputter process chambers, including those from other manufactures, may be adapted to practice the present invention.

The processing chamber 400 includes a top wall 404, a bottom wall 402, a front wall 406 and a back wall 408, enclosing an interior processing region 440 within the processing chamber 400. At least one of the walls 402, 404, 406, 408 is electrically grounded. The front wall 406 includes a front substrate transfer port 418 and the back wall 408 includes a back substrate transfer port 432 that facilitate substrate entry and exit from the processing chamber 400. The front transfer port 418 and the back transfer port 432 may be slit valves or other suitable sealable doors that can maintain vacuum within the processing chamber 400. The transfer ports 418, 432 may be coupled to a transfer chamber, load lock chamber and/or other chambers of a substrate processing system.

One or more PVD targets 434, 420 may be mounted to the top wall 404 to provide a material source that can be sputtered from the target 434, 420 and deposited onto the surface of the substrate 102 during a PVD process. The target 434, 420 may be fabricated from a material utilized for deposition species. High voltage power supplies, such as power sources 430, are connected to the target 434, 420 to facilitate sputtering materials from the target 434, 420.

Each of the target 434, 420 disposed in the processing chamber 400 may contain the same or different target materials as needed to deposit layers on the surface of the substrate 102. In one embodiment, the target 434, 420 disposed in the processing chamber 400 is configured to have different materials, so that the substrate 102 transported thereunder may have different material layers sequentially formed thereon. In one embodiment, the first target 434 may be configured to have a silicon containing target, such as a silicon target, so as to provide silicon source to be sputtered therefrom to form the barrier layer, such as the barrier layer 202 depicted with referenced to FIGS. 1, 2A-B and 3 on the substrate surface. In the embodiment wherein the barrier layer 202 is configured to form as a silicon oxynitride layer, the material of the target 434 may be a silicon target and a gas mixture containing nitrogen gas and oxygen gas from a gas source 428 are supplied into the processing chamber 400, the materials dislodged from the target surface may react with the dislodged material, forming silicon oxynitride on the surface of the substrate 102. It is noted that the types of gas supplied into the processing region 440 and the source material of the target 434 used may be varied and changed as needed to form different types of barrier layer 202 on the substrate 102.

The second target 420 may be fabricated from a material containing zinc (Zn) metal. In another embodiment, the target 420 may be fabricated from materials including metallic zinc (Zn), zinc alloy, zinc oxide and the like. Different dopant materials, such as boron containing materials, titanium containing materials, tantalum containing materials, tungsten containing materials, aluminum containing materials, and the like, may be doped into a zinc containing base material to form a target with a desired dopant concentration. In one embodiment, the dopant materials may include one or more of boron containing materials, titanium containing materials, tantalum containing materials, aluminum containing materials, tungsten containing materials, alloys thereof, combinations thereof and the like. In one embodiment, the target 420 may be fabricated from a zinc oxide material having dopants, such as, titanium oxide, tantalum oxide, tungsten oxide, aluminum oxide, aluminum metal, boron oxide and the like, doped therein. In one embodiment, the dopant concentration in the zinc containing material comprising the target 420 is controlled to less than about 10 percent by weight. In one embodiment, the target 420 is fabricated from a zinc and aluminum alloy having a desired ratio of zinc element to aluminum element. The aluminum elements comprising the target 420 assists maintaining the target conductivity within a desired range so as to efficiently enable a uniform sputter process across the target surface. The aluminum elements in the target 420 is also believed to increase film transmittance when sputtered off and deposited onto the substrate 102. In one embodiment, the concentration of the aluminum element comprising the zinc target 420 is controlled to less than about 5 percent by weight. In embodiments wherein the target 420 is fabricated from ZnO and Al₂O₃ alloy, the Al₂O₃ dopant concentration in the ZnO base target material is controlled to less than about 2 percent by weight, such as less than 0.5 percent by weight, for example, about 0.25 percent by weight.

In operation, when the substrate 102 is transferred into the processing chamber 400 through the back transfer ports 432, the substrate 102 is then first transferred under the first target 434 to receive the first material sputtered from the first target 434. The first material dislodged from the first target 434 forms the barrier layer 202 on the substrate 102. Subsequently, the substrate 102 is further transferred and advanced under the second target 420 to receive the second material from the second target 420. The second material dislodged from the second target 420 forms the TCO layer 104 over the barrier layer 202 on the substrate 102. After the material layers are formed on the substrate 102, the substrate 102 may be further transported and removed out of the processing chamber 400 from the front transfer ports 418.

Optionally, a magnetron assembly (not shown) may be optionally mounted above the targets 434, 420 which enhances efficient sputtering materials from the target 434, 420 during processing. Examples of the magnetron assembly include a linear magnetron, a serpentine magnetron, a spiral magnetron, a double-digitated magnetron, a rectangularized spiral magnetron, among others.

A gas source 428 supplies process gases into the processing volume 140 through a gas supply inlet 426 formed through the top wall 404 and/or other wall of the processing chamber 400. In one embodiment, process gases may include inert gases, non-reactive gases, and reactive gases. Examples of process gases that may be provided by the gas source 428 include, but not limited to, argon gas (Ar), helium (He), nitrogen gas (N₂), oxygen gas (O₂), H₂, NO₂, N₂O and H₂O among others. It is noted that the location, number and distribution of the gas source 428 and the gas supply inlet 426 may be varied and selected according to different designs and configurations of the specific processing chamber 400. In one embodiment, the process gases supplied to the processing chamber 400 during the sputtering process may be varied or changed at different deposition stage of the process to form the barrier layer 202 with different elements therein. For example, different process gases may be supplied into the processing chamber 400 while sputtering the materials from the targets 434, 420 to form the barrier layer 202 or the TCO layer 104 as gradient films or multiple layers as needed.

A pumping device 442 is coupled to the processing region 440 to evacuate and control the pressure therein. In one embodiment, the pressure level of the interior processing region 440 of the processing chamber 400 may be maintained at about 1 Torr or less. In another embodiment, the pressure level within the processing chamber 400 may be maintained at about 10⁻³ Torr or less. In yet another embodiment, the pressure level within the processing chamber 400 may be maintained at about 10⁻⁵ Torr to about 10⁻⁷ Torr. In another embodiment, the pressure level of the processing chamber 400 may be maintained at about 10⁻⁷ Torr or less.

A substrate carrier system 452 is disposed in the interior processing region 440 to carry and convey a plurality of substrates 102 disposed in the processing chamber 400. In one embodiment, the substrate carrier system 452 is disposed on the bottom wall 402 of the processing chamber 400. The substrate carrier system 452 includes a plurality of cover panels 414 disposed among a plurality of rollers 412. The rollers 412 may be positioned in a spaced-apart relationship. The rollers 412 may be actuated by actuating device (not shown) to rotate the rollers 412 about an axis 464 fixedly disposed in the processing chamber 400. The rollers 412 may be rotated clockwise or counter-clockwise to advance (a forward direction shown by arrow 416a) or backward (a backward direction shown by arrow 416b) the substrates 102 disposed thereon. As the rollers 412 rotate, the substrate 102 is advanced over the cover panels 414. In one embodiment, the rollers 412 may be fabricated from a metallic material, such as Al, Cu, stainless steel, or metallic alloys, among others.

A top portion of the rollers 412 is exposed to the processing region 440 between the cover panels 414, thus defining a substrate support plane that supports the substrate 102 above the cover panels 414. During processing, the substrates 102 enter the processing chamber 400 through the back access port 432. One or more of the rollers 412 are actuated to rotate, thereby advancing the substrate 102 across the rollers 412 in the forward direction 416a through the processing region 440 for deposition. As the substrate 102 advances, the material sputtered from the target 434, 420 falls down and deposits on the substrate 102 to form a TCO layer with desired film properties. As the substrate 102 continues to advance, the materials sputtered from different targets 434, 420 are consecutively deposited on the substrate surface, thereby forming a desired layer of TCO film on the substrate surface.

In order to deposit the barrier layer 202 and TCO layer 104 on the substrate 102 with high quality, an optional insulating member 410 electrically isolates the rollers 412 from ground. In one embodiment, the insulating member 410 may be in form of an insulating pad fabricated from an insulating material, such as rubber, glass, polymer, plastic, and polyphenylene sulfide (PPS), polyetheretherketone (PEEK) or any other suitable insulating materials that can provide insulation to the rollers to the bottom wall 402 of the processing chamber 400. In one embodiment, the insulating member 410 is a non-conductive material, such as polyphenylene sulfide (PPS), polyetheretherketone (PEEK), or the like.

A controller 448 is coupled to the processing chamber 400. The controller 448 includes a central processing unit (CPU) 460, a memory 458, and support circuits 462. The controller 448 is utilized to control the process sequence, regulating the gas flows from the gas source 428 into the processing chamber 400 and controlling ion bombardment of the target 434, 420. The CPU 460 may be of any form of a general purpose computer processor that can be used in an industrial setting. The software routines can be stored in the memory 458, such as random access memory, read only memory, floppy or hard disk drive, or other form of digital storage. The support circuits 462 are conventionally coupled to the CPU 460 and may comprise cache, clock circuits, input/output subsystems, power supplies, and the like. The software routines, when executed by the CPU 460, transform the CPU into a specific purpose computer (controller) 448 that controls the processing chamber 400 such that the processes are performed in accordance with the present invention. The software routines may also be stored and/or executed by a second controller (not shown) that is located remotely from the processing chamber 400.

During processing, as the substrate 102 is advanced by the roller 412, the material is sputtered from the targets 434, 420 and sequentially deposited on the surface of the substrate 102. The targets 434, 420 is biased by the power source 430 to maintain a plasma 422, 436 formed from the process gases supplied by the gas source 428 and biased toward the substrate surface (as shown by arrows 438, 424). The ions from the plasma are accelerated toward and strike the targets 434, 420, causing target material to be dislodged from the target 434, 420. The dislodged target material and process gases sequentially form layers on the substrate 102 with a desired composition.

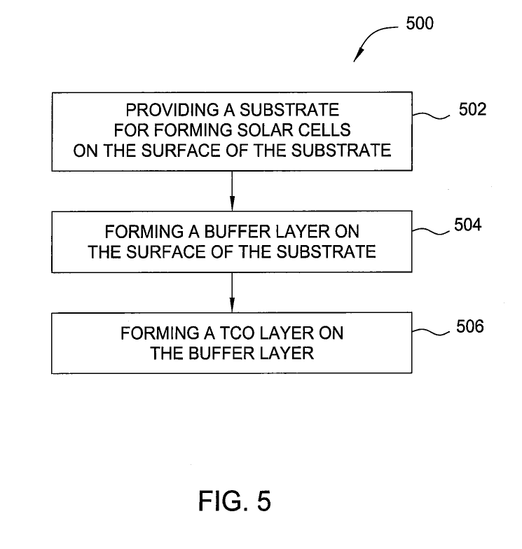

FIG. 5 depicts a flow diagram of a process sequence for fabricating the barrier layer 202 for where the TCO layer 104 may be formed thereon in accordance with one embodiment of the present invention. The process 500 starts at step 502 by providing the substrate 102 into a processing chamber, such as the processing chamber 400 depicted in FIG. 4. The substrate 102 may be utilized to form a single junction or multiple junction solar cells 100, 300 as described above with referenced to FIGS. 1, 2A-B and 3. In one embodiment, the substrate 102 is a glass substrate, a polymer substrate, or any suitable transparent substrate that allows sunlight to pass therethrough.

At step 504, after the substrate 102 is transferred into the processing chamber 400, a RF or a DC power is supplied to the first target 434 to dislodge materials from the first target 434 to deposit the barrier layer 202 on the substrate surface. During sputtering of the first target 434, the process gas may be supplied to the processing region 440 to assist bombardment of the materials dislodged from the first target 434 and react with the dislodged material to form the barrier layer 202 with desired film properties on the substrate surface. In one embodiment, the process gas mixture supplied from the gas source 428 may be varied as the roller 412 rotates to advance the substrate 102 forward. As the process gas mixture changes, the materials and film properties formed on the substrate surface may be varied as well, thereby forming a gradient film or multiple film layers on the substrate surface. In the embodiment wherein the first target 434 is configured as a silicon target, the process gas mixture supplied into the processing chamber 400 may contain nitrogen gas, oxygen gas and optional an inert gas, such as He or Ar. The nitrogen gas and the oxygen gas supplied into the processing region 440 react with the silicon material dislodged from the first target 434, forming a silicon oxynitride (SiON) as the barrier layer 202 on the substrate surface. The amount of nitrogen gas supplied into the processing chamber 400 may be controlled less than the amount of oxygen gas supplied thereto so as to form the barrier layer 202 as an oxygen rich SiON layer which may promote growth of the TCO layer 104 subsequently formed thereon.

In another embodiment, the process gas mixture supplied into the processing chamber 400 to form the barrier layer 202 may be controlled at a certain amount so as to form multiple layers on the substrate surface with different desired film properties. For example, a nitrogen containing gas, such as N₂ gas, may be supplied into the processing chamber 400 to form a SiN layer as the first layer, such as the lower layer 206 depicted in FIG. 2, on the substrate surface. Subsequently, the process gas supplied into the processing chamber 400 is switched to an oxygen containing gas, such as O₂ gas, to form a SiO₂ layer as the second layer, such as the upper layer 208 as depicted in FIG. 2, over the first layer 206. As discussed above, as the upper layer 208 has a contact surface 210 that will be in contact with the TCO layer 104 subsequently disposed thereon, an oxygen rich surface is desired to promote grain growth and nucleation of the TCO layer 104. Accordingly, the upper layer 208 is configured to form as an oxygen rich layer, such as a SiO₂ layer. In yet another embodiment, after sputtering process performed under the first target 434 and deposit a dielectric layer, such as the barrier layer 202, on the substrate 102, the RF bombardment to the first target 434 may be temporarily ceased to remain only plasma on the processing chamber 400 to allow a surface treatment process being performed on the barrier layer 202 formed on the substrate surface. The surface treatment process may be performed to treat the surface 210 of the barrier layer 202 as an oxygen rich surface that may also promote grain growth and nucleation of the TCO layer 104. In this configuration, the barrier layer 202 may be in form of any silicon containing layer, including SiN, SiON, SiO₂, so the oxygen rich surface may be obtained by performing the oxygen surface treatment process as discussed.

At step 506, after the barrier layer 202 is formed on the substrate 102, the substrate 102 is then advanced forward to under the second target 420 disposed on the top wall 404 of the processing chamber 400. As the substrate 102 is positioned under the second target 420, a RF or a DC power is supplied to the second target 420 to dislodge materials from the second target 420. The substrate 102 then receives the dislodged materials from the second target 420, forming the TCO layer 104 over the barrier layer 202 on the surface of the substrate 102.

In one embodiment, the RF power supplied into the both the first and the second target 434, 420 at step 504 and 506 may be controlled at 100 Watts and about 60000 Watts. Alternatively, the RF power may be controlled by RF power density supplied between about 0.15 Watts per centimeter square and about 15 Watts per centimeter square, for example, about 4 Watts per centimeter square and about 8 Watts per centimeter square. Alternatively, the DC power may be supplied between about 0.15 Watts per centimeter square and about 15 Watts per centimeter square. The sputter time of each of the target 434, 420 may be controlled at between about 100 seconds and about 500 seconds or until a desired thickness has archived for both the barrier layer 202 and the TCO layer 104. The chamber pressure between about between about 2 mTorr and about 10 mTorr. The gas flow rate supplied during sputtering the first target 434 at step 504 may be controlled at a predetermined rate as well. In one embodiment, the nitrogen gas supplied while sputtering is controlled between about 1 sccm/L and about 100 sccm/L by volume. The oxygen gas supplied while sputtering is controlled between about 1 sccm/L and about 100 sccm/L by volume. The inert gas, such as Ar or He, supplied while sputtering is controlled between about 1 sccm/L and about 100 sccm/L by volume. Furthermore, the gas flow rate supplied during sputtering the second target 420 at step 506 may be controlled at a predetermined rate as well. In one embodiment, the nitrogen gas supplied while sputtering is controlled between about 1 sccm/L and about 100 sccm/L by volume. The oxygen gas supplied while sputtering is controlled between about 1 sccm/L and about 100 sccm/L by volume. The inert gas, such as Ar or He, supplied while sputtering is controlled between about 1 sccm/L and about 100 sccm/L by volume.

It is noted that the barrier layer 202 may also be formed in any other suitable deposition techniques, such as CVD, ALD, EPI or any other deposition processes that may provide an oxygen rich and/or low nitrogen concentration film surface that may allow grain and nucleation site growth of the TCO layer 104 formed thereon.

After forming the TCO layer 104 on the substrate 102, an optional surface treatment process, such as a wet etching, dry etching or surface texturing process, may be performed to roughen the surface of the TCO layer 104. It is believed that the TCO layer 104 having a certain degree of surface roughness may assist trapping lights in the TCO layer 104 for a longer time and scattering light to the junction cells subsequently formed thereon. Accordingly, the optional surface treatment process, or surface roughening process may be performed on the TCO layer 104 to form a roughened surface on the surface of the TCO layer 104. In one embodiment the surface roughness process may be performed by a wet etching process by using a batch cleaning process in which the TCO layer 104 on the substrate 102 is exposed to a cleaning solution. The TCO layer 104 may be textured using a wet cleaning process in which they are sprayed, flooded, or immersed in a cleaning solution. The clean solution may be an SC1 cleaning solution, an SC2 cleaning solution, HF-last type cleaning solution, diluted HCl containing solution, ozonated water solution, hydrofluoric acid (HF) and hydrogen peroxide (H₂O₂) solution, or other suitable and cost effective cleaning solution. The wet etching process may be performed on the substrate 102 between about 5 seconds and about 600 seconds, such as about 30 seconds to about 240 second, for example about 120 seconds.

Thus, methods and apparatus for forming a barrier layer between a substrate and a TCO layer for fabricating solar cell devices are provided. The barrier layer advantageously provides a good interface to grow grains and nucleation sites that allows the TCO layer subsequently deposited thereon having high adhesion and desired columnar grain structure, thereby efficiently improving the photoelectric conversion efficiency and device performance of the solar cells.

While the foregoing is directed to embodiments of the present invention, other and further embodiments of the invention may be devised without departing from the basic scope thereof, and the scope thereof is determined by the claims that follow.

What is claimed is:

1. A photovoltaic device, comprising:
a barrier layer disposed on a substrate;
a TCO layer disposed on the barrier layer; and
a p-i-n junction cell formed on the TCO layer.

2. The photovoltaic device of claim 1, wherein the barrier layer is a dielectric layer.

3. The photovoltaic device of claim 1, wherein the barrier layer has a top surface in contact with the TCO layer having a nitrogen concentration less than 40 weight percent.

4. The photovoltaic device of claim 1, wherein the barrier layer having a upper layer in contact with the TCO layer and a lower layer, wherein the upper layer has a oxygen rich surface.

5. The photovoltaic device of claim 4, wherein the upper layer is a silicon oxide layer.

6. The photovoltaic device of claim 4, wherein the upper layer is an oxygen gas treated layer.

7. The photovoltaic device of claim 4, wherein the lower layer is a dielectric layer selected from the group consisting of silicon nitride, silicon oxynitride, silicon oxide and combinations thereof.

8. The photovoltaic device of claim 4, wherein the upper layer has a thickness between about 600 Åand about 1200 Åand the lower layer has a thickness between about 200 Åand about 600 Å.

9. The photovoltaic device of claim 1, wherein the barrier layer has a thickness between about 800 Åand about 1800 Å.

10. The photovoltaic device of claim 1, wherein the barrier layer has a top surface in contact with the TCO layer having a nitrogen concentration less than 40 weight percent.

11. A method for forming a photovoltaic device, comprising:
providing a substrate having a surface;
forming a barrier layer on the surface of the substrate;
forming a TCO layer on a top surface of the barrier layer; and
forming a p-i-n junction cell on the TCO layer.

12. The method of claim 11, wherein forming the barrier layer further comprises:
depositing the barrier layer by a sputter process that sputters material from a silicon containing target to deposit on the substrate surface.

13. The method of claim 12, wherein depositing the barrier layer further comprises:
supplying a first gas mixture to react with the sputtered material from the silicon containing target to form a first layer on the substrate surface; and
supplying a second gas mixture to react with the sputtered material from the silicon containing target to form a second layer on the first layer.

14. The method of claim 13, wherein the first gas mixture includes at least a nitrogen containing gas.

15. The method of claim 13, wherein the second gas mixture includes at least an oxygen containing gas.

16. The method of claim 13, wherein the first layer is a silicon nitride or silicon oxynitride layer.

17. The method of claim 13, wherein the second layer is a silicon oxide or silicon oxynitride layer.

18. The method of claim 13, wherein the second layer has a top surface in contact with the TCO layer having a nitrogen concentration less than 40 weight percent.

19. The method of claim 11, wherein forming the barrier layer further comprises:
plasma treating the top surface of the barrier layer by an oxygen containing gas to form an oxygen rich surface thereon.

20. The method of claim 11, wherein the barrier layer and the TCO layer are formed in a single chamber.

21. A photovoltaic device, comprising:
a first dielectric layer disposed on a substrate;
a second dielectric layer disposed on the first dielectric layer on the substrate, wherein the second dielectric layer has a top surface having a nitrogen concentration less than 40 weight percent;
a TCO layer disposed on the second dielectric layer; and
a p-i-n junction cell formed on the TCO layer.

22. The photovoltaic device of claim 21, wherein the top surface of the second dielectric layer is an oxygen rich film having a oxygen concentration greater than 60 weight percent.

23. The photovoltaic device of claim 21, wherein the second dielectric layer is an oxygen treated layer.

24. The photovoltaic device of claim 21, wherein the first layer is a silicon nitride layer or a silicon oxynitride layer having a thickness between about 600 Å and about 1200 Å.

25. The photovoltaic device of claim 21, wherein the first layer is a silicon oxide layer or a silicon oxynitride layer having a thickness between about 600 Åand about 1200 Å.
